(19) United States
(12) Patent Application Publication
(10) Pub. No.: US 2019/0140015 A1
(43) Pub. Date: May 9, 2019

(54) HORTICULTURAL LIGHTING DEVICES AND METHODS

(71) Applicant: The Green Sunshine Company, LLC, Portland, OR (US)

(72) Inventor: Daniel Drazba, Portland, OR (US)

(21) Appl. No.: 16/174,910

(22) Filed: Oct. 30, 2018

Related U.S. Application Data
(60) Provisional application No. 62/583,732, filed on Nov. 9, 2017.

(51) Int. Cl. H01L 27/15; A01G 7/04; F21K 9/64; H01L 33/50

(52) U.S. Cl. CPC H01L 27/156; H01L 33/507; F21K 9/64; A01G 7/045

(57) ABSTRACT

Horticultural lighting devices and methods are disclosed herein. The methods include generating an LED-based horticultural light spectrum at a radiant flux. The horticultural lighting devices include a light fixture configured to receive and to operate plural light-emitting diodes (LEDs). The horticultural lighting device also includes a plurality of LEDs, coupled to the light fixture, that generate a radiant flux. For both the methods and the horticultural lighting devices, 7%-15% of the radiant flux is from light with wavelengths in a blue light band of 400 nanometers (nm) to less than 500 nm, 20%-40% of the radiant flux is from light with wavelengths in a green light band of 500 nm to less than 600 nm, and 45%-60% of the radiant flux is from light with wavelengths in a red light band of 600 nm to less than 700 nm.

### RELATED APPLICATION

This application claims priority to U.S. Provisional Patent Application No. 62/583,732, which is entitled HORTICULTURAL LIGHTING DEVICES AND METHODS, was filed on Nov. 9, 2017, and the complete disclosure of which is hereby incorporated by reference.

### FIELD OF THE DISCLOSURE

The present disclosure relates generally to horticultural lighting devices and methods and more specifically to horticultural lighting relating to growing plants and devices and methods relating thereto.

### BACKGROUND OF THE DISCLOSURE

Some horticultural lighting devices employ light-emitting diodes (LEDs), which may operate at lower temperatures and/or lower power usage than other horticultural lighting devices. Early LED horticultural lighting devices employed mono-color narrowband LEDs that typically generated primarily red light or blue light. As a result, such LED horticultural lighting devices exhibited a “green gap” phenomenon, meaning they created a relatively low proportion of green light in the color spectrum. This green gap resulted in relatively low growth of plants illuminated by such early LED horticultural lighting devices. In addition, some LEDs used in such early LED horticultural lighting devices were relatively inefficient and required supplemental cooling to maintain operating efficiency, which added to both initial and longer-term operating costs.

Subsequently, some LEDs (e.g., phosphor-converted (PC) LEDs) were developed to generate white light, and some LED horticultural lighting devices were configured to employ such white PC LEDs. While providing increased efficiency and affordability, and being operable with passive cooling (e.g., no fans required), such white PC LEDs are designed for maximum brightness to the human eye, and not a spectrum that is optimal for plant growth. Thus, there exists a need for improved horticultural lighting devices and methods.

### SUMMARY OF THE DISCLOSURE

Horticultural lighting devices and methods are disclosed herein. The methods include generating an LED-based horticultural light spectrum at a radiant flux. The horticultural lighting devices include a light fixture configured to receive and to operate plural light-emitting diodes (LEDs). The horticultural lighting device also includes a plurality of LEDs, coupled to the light fixture, that generate a radiant flux. For both the methods and the horticultural lighting devices, 7%-15% of the radiant flux is from light with wavelengths in a blue light band of 400 nanometers (nm) to less than 500 nm, 20%-40% of the radiant flux is from light with wavelengths in a green light band of 500 nm to less than 600 nm, and 45%-60% of the radiant flux is from light with wavelengths in a red light band of 600 nm to less than 700 nm.

### BRIEF DESCRIPTION OF THE DRAWINGS

FIG. 1 is an illustration of an example of a horticultural lighting device according to the present disclosure.

FIG. 2 is a block diagram illustrating examples of a horticultural lighting device, according to the present disclosure, emitting light to illuminate plants.

FIG. 3 is a bar graph illustrating proportional ranges of radiant flux of an LED-based horticultural light spectrum according to the present disclosure.

FIG. 4 is an illustration of relative light intensity as a function of wavelength for an example of an LED-based horticultural light spectrum that may be generated utilizing horticultural lighting devices and/or during methods, according to the present disclosure.

FIG. 5 is an illustration of relative light intensity as a function of wavelength for an example of a wideband phosphor-converted (PC) red LED that may be utilized with horticultural lighting devices and/or during methods, according to the present disclosure.

FIG. 6 is an illustration of relative light intensity as a function of wavelength for an example of a PC white LED that may be utilized with horticultural lighting devices and/or during methods, according to the present disclosure.

FIG. 7 is an illustration of relative light intensity as a function of wavelength for another example of a PC white LED that may be utilized with horticultural lighting devices and/or during methods, according to the present disclosure.

FIG. 8 is an illustration of relative light intensity as a function of wavelength for another example of a PC white LED that may be utilized with horticultural lighting devices and/or during methods, according to the present disclosure.

FIG. 9 is an illustration of relative light intensity as a function of wavelength for another example of a PC white LED that may be utilized with horticultural lighting devices and/or during methods, according to the present disclosure.

FIG. 10 is an illustration of relative light intensity as a function of wavelength for another example of an LED-based horticultural light spectrum that may be generated utilizing horticultural lighting devices and/or during methods, according to the present disclosure.

### DETAILED DESCRIPTION AND BEST MODE OF THE DISCLOSURE

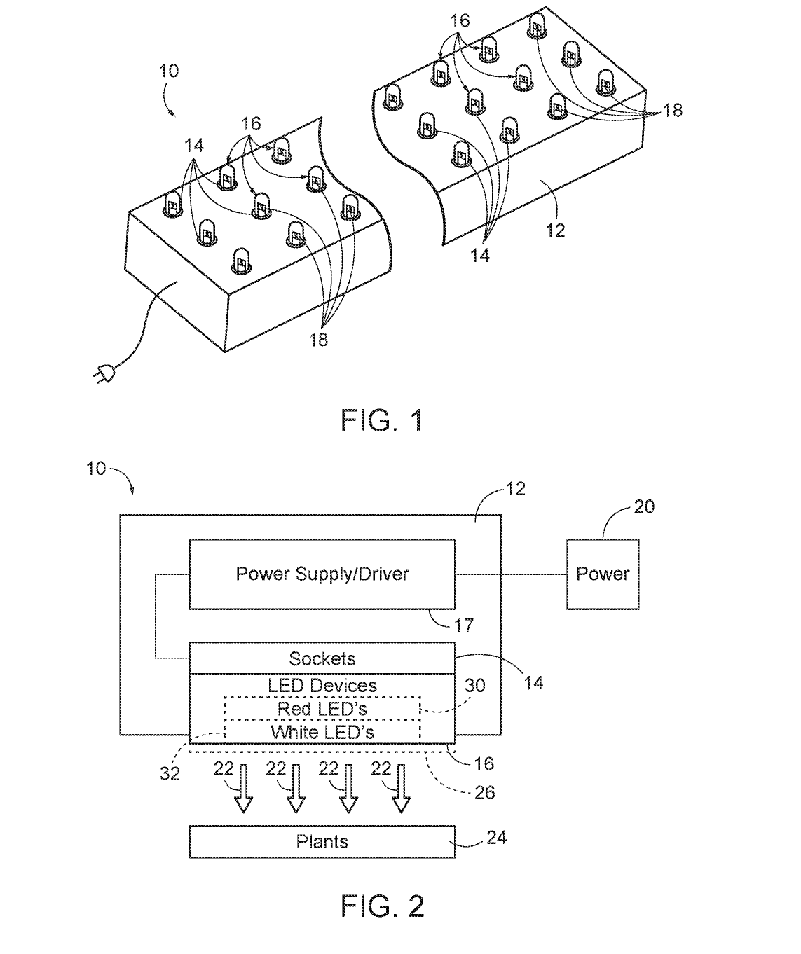

FIGS. 1-10 provide examples of horticultural lighting devices 10 and/or of LED-based horticultural light spectra 150, according to the present disclosure. Elements that serve a similar, or at least substantially similar, purpose are labeled with like numbers in each of FIGS. 1-10, and these elements may not be discussed in detail herein with reference to each of FIGS. 1-10. Similarly, all elements may not be labeled in each of FIGS. 1-10, but reference numerals associated therewith may be utilized herein for consistency. Elements, components, and/or features that are discussed herein with reference to one or more of FIGS. 1-10 may be included in and/or utilized with any of FIGS. 1-10 without departing from the scope of the present disclosure.

In general, elements that are likely to be included in a particular embodiment are illustrated in solid lines, while elements that are optional are illustrated in dashed lines. However, elements that are shown in solid lines may not be essential and, in some embodiments, may be omitted without departing from the scope of the present disclosure.

FIG. 1 is an illustration of a horticultural lighting device 10 that includes a lighting fixture 12 with multiple sockets 14 that are configured to receive respective ones of multiple light-emitting diode (LED) devices 16. Accordingly, horticultural lighting device 10 may be referred to as an LED horticultural lighting device 10, and lighting fixture 12 may be referred to as an LED lighting fixture 12. In the example of FIG. 1, each LED device 16 includes one LED 18. In other examples, one or more of LED devices 16 may include a plurality of LEDs 18. In some other examples, LED devices 16 may be connected to LED lighting fixture 12 without sockets 14, such as by fixed and/or permanent coupling (e.g., soldering).

As shown in the block diagram of FIG. 2, horticultural lighting device 10 may further include an LED power supply/driver 17 that may receive power from a power source 20, such as a mains, line, and/or domestic power source, a self-generating (e.g., solar) power source, and/or a stored (e.g., battery) power source. The power may be utilized to power and/or to operate LED devices 16 to generate light 22. In operation, lighting fixture 12 may be positioned and/or oriented to direct light 22 from LED devices 16 toward one or more growing plants 24 to provide horticultural illumination that supports photosynthesis in plants 24, photosynthetic development of plants 24, and/or growth of plants 24. In some examples, horticultural lighting device 10, lighting fixture 12, and/or LED devices 16 may include one or more optical elements 26, such as a lens and/or a diffuser, that may position and/or distribute the light onto and/or over plants 24.

In some examples, LED devices 16 may include a first multiplicity, a first plurality, or a first set of red LEDs 30 and a second multiplicity, a second plurality, or a second set of white LEDs 32. As discussed in more detail herein, the red LEDs 30 in some examples may be characterized as wideband red LEDs. Examples of the wideband red LEDs include phosphor-converted (PC) red LEDs, which may be referred to as wideband PC red LEDs 30. Examples of such wideband PC red LEDs are sold by OSRAM Opto Semiconductors GmbH under the DURIS™ brand, including the S 5 PSLR31.13 LED product, for example. Similarly, the white LEDs 32 may be or include PC white LEDs, examples of which also are sold by OSRAM Opto Semiconductors GmbH under the DURIS™ brand, including the S 5 PSLR31.EM LED product.

As discussed, horticultural lighting device 10 may be configured to direct light 22 incident upon plants 24, such as to promote and/or facilitate growth of the plants. In addition, and as discussed in more detail herein, horticultural lighting device 10 may produce and/or generate light 22 with certain specific, defined, and/or selected spectral characteristics that may promote and/or facilitate improved plant growth when compared to conventional horticultural lighting devices that do not generate light with similar spectral characteristics.

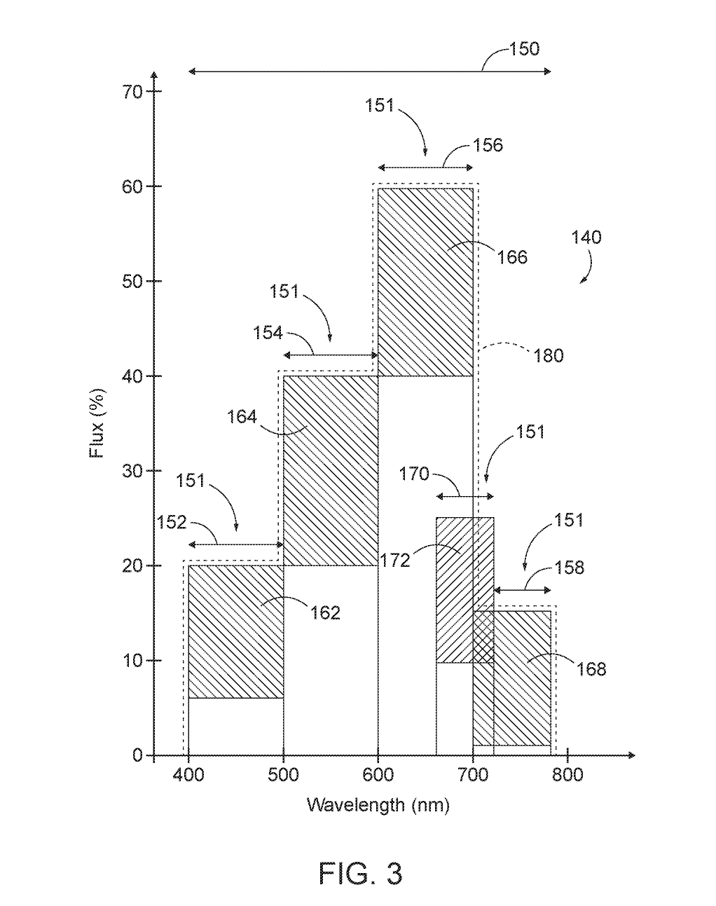

With the above in mind, FIG. 3 is a bar graph 140 illustrating proportional ranges of radiant flux of an LED-based horticultural light spectrum 150 that may be produced and/or generated by horticultural lighting device 10, according to the present disclosure. Stated another way, light 22 generated by horticultural lighting devices 10 of FIGS. 1-2 may have, define, and/or exhibit the proportional ranges of radiant flux illustrated by LED-based horticultural light spectrum 150 of FIG. 3.

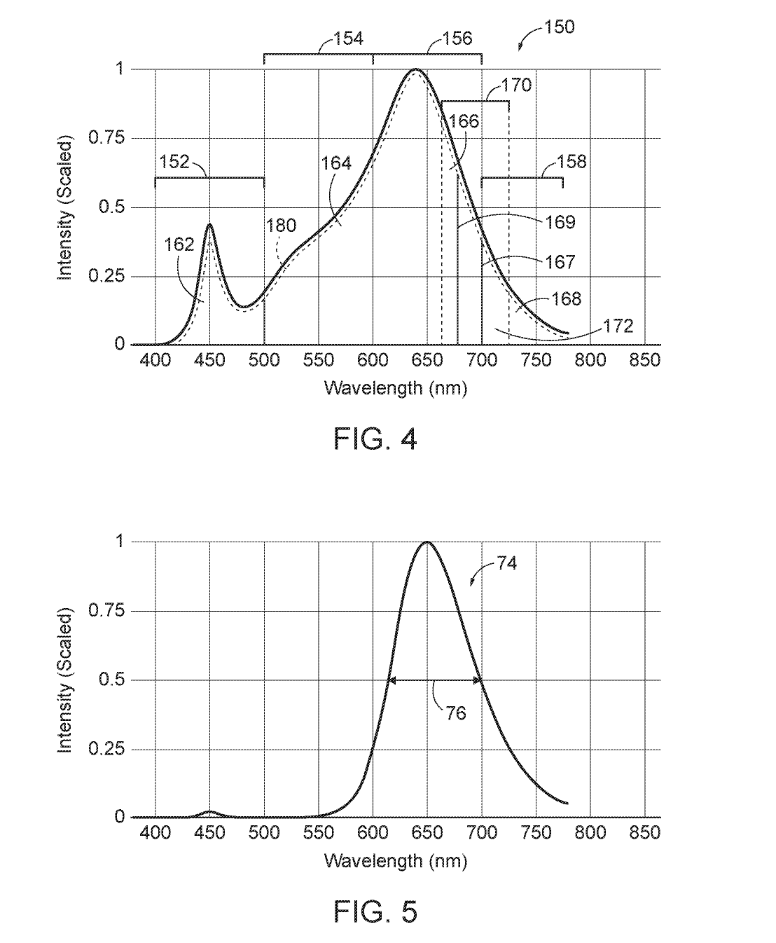

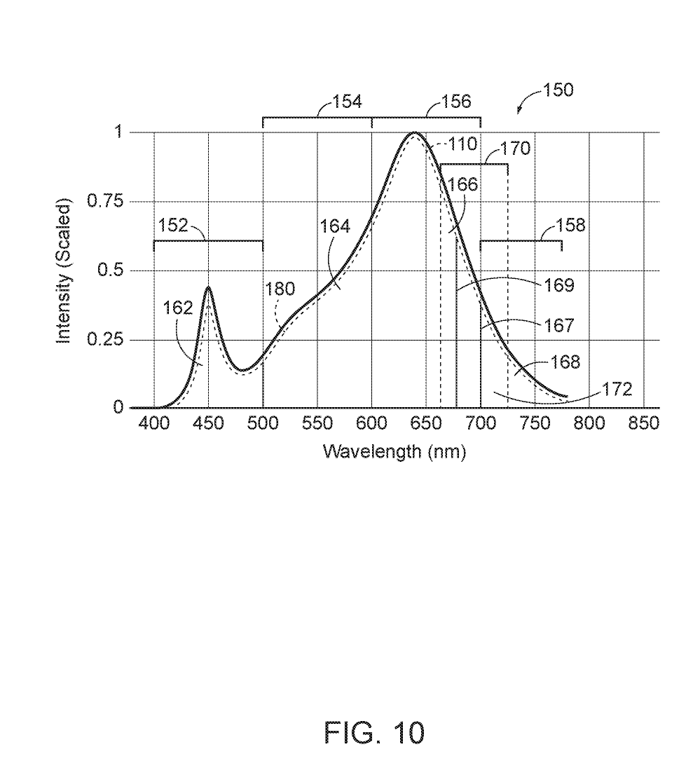

LED-based horticultural light spectrum 150 illustrates ranges of radiant flux that are otherwise shown as particular examples in FIGS. 4 and 10 and discussed in more detail herein with reference thereto. As illustrated in bar graph 140, LED-based horticultural light spectrum 150 may be divided, or may be referred to herein as being divided, into a plurality of light bands, or ranges, 151.

More specifically, bar graph 140 illustrates a generally blue light band 152, which also may be referred to herein as blue light 152, a generally green light band 154, which also may be referred to herein as green light 154, a generally red light band 156, which also may be referred to herein as red light 156, and a near-infrared light band 158, which also may be referred to herein as near IR light 158. Bar graph 140 also illustrates that LED-based horticultural light spectrum 150 may include a photosystem light band 170, which also may be referred to herein as photosystem light 170.

Blue light band 152 may include light with a wavelength between 400 nm and 500 nm and may have and/or define a blue light band radiant flux 162, which also may be referred to herein as a radiant flux 162 and/or as blue light radiant flux 162. Green light band 154 may include light with a wavelength between 500 nm and 600 nm and may have and/or define a green light band radiant flux 164, which also may be referred to herein as a radiant flux 164 and/or as green light radiant flux 164. Red light band 156 may include light with a wavelength between 600 nm and 700 nm and may have and/or define a red light band radiant flux 166, which also may be referred to herein as a radiant flux 166 and/or as red light radiant flux 166. Near-infrared light band 158 may include light with a wavelength between 700 nm and 780 nm and may have and/or define a near-infrared light band radiant flux 168, which also may be referred to herein as a radiant flux 168 and/or as near IR light radiant flux 168. Photosystem light band 170 may include light with a wavelength between 660 nm and 720 nm and may have and/or define a photosystem light band radiant flux 172, which also may be referred to herein as a radiant flux 172 and/or as photosystem radiant flux 172.

The radiant flux from a given light band 151, such as radiant flux 162, radiant flux 164, radiant flux 166, radiant flux 168, and/or radiant flux 172, also may be referred to herein as a radiant power for the given light band and may correspond to the energy, or power, emitted, or radiated, in the given light band per unit time. In the metric, or International System of Units (SI), system, radiant flux may have units of watts. In FIG. 3, each light band 151 may exhibit a range of corresponding radiant flux values. This range of corresponding radiant flux values is illustrated in cross-hatching in FIG. 3 and discussed in more detail herein with reference to each individual light band 151.

In the example of FIG. 3, a total radiant flux 180 of LED-based horticultural light spectrum 150 may be defined as a mathematical sum of the overall radiant flux of the horticultural light spectrum. Stated another way, total radiant flux 180 may be defined as a sum of radiant flux 162, radiant flux 164, radiant flux 166, and radiant flux 168. Radiant flux 172 may not be explicitly included in the above definition of total radiant flux 180 since radiant flux 172 includes light from red light band 156 and near-infrared light band 158, which already are included in total radiant flux 180.

Blue light band radiant flux 162 may form a blue light fraction of total radiant flux 180. Examples of the blue light fraction include fractions of at least 6%, at least 7%, at least 8%, at least 9%, at least 10%, at least 11%, at least 12%, at least 13%, at least 14%, and/or at least 15%. Additional examples of the blue light fraction include fractions of at most 21%, at most 20%, at most 19%, at most 18%, at most 17%, at most 16%, at most 15%, at most 14%, at most 13%, and/or at most 12%.

Green light radiant flux 164 may form a green light fraction of total radiant flux 180. Examples of the green light fraction include fractions of at least 20%, at least 21%, at least 22%, at least 23%, at least 24%, at least 25%, at least 26%, at least 27%, at least 28%, at least 29%, at least 30%, at least 31%, at least 32%, and/or at least 33%. Additional examples of the green light fraction include fractions of at most 40%, at most 39%, at most 38%, at most 37%, at most 36%, at most 35%, at most 34%, at most 33%, at most 32%, at most 31%, at most 30%, at most 29%, at most 28%, and/or at most 27%.

Red light radiant flux 166 may form a red light fraction of total radiant flux 180. Examples of the red light fraction include fractions of at least 40%, at least 41%, at least 42%, at least 43%, at least 44%, at least 45%, at least 46%, at least 47%, at least 48%, at least 49%, at least 50%, at least 51%, at least 52%, and/or at least 54%. Additional examples of the red light fraction include fractions of at most 60%, at most 59 %, at most 58%, at most 57%, at most 56%, at most 55%, at most 54%, at most 53%, at most 52%, at most 51%, at most 50%, at most 49%, at most 48%, and/or at most 47%.

Near-infrared light band radiant flux 168 may form an IR light fraction of total radiant flux 180. Examples of the IR light fraction include fractions of at least 1%, at least 2%, at least 3%, at least 4%, at least 5%, at least 6%, at least 7%, and/or at least 8%. Additional examples of the IR light fraction include fractions of at most 15%, at most 14%, at most 13%, at most 12%, at most 11%, at most 10%, at most 9%, at most 8%, and/or at most 7%.

Photosystem light band 170 may include photosystem I active light (e.g., at or about 700 nm) and photosystem II active light (e.g., at or about 680 nm) that are active in photosynthetic operation. Photosystem light band 170 extends between 660 nm and 720 nm and includes photosystem I active light, photosystem II active light, and wavelengths within 20 nm of each. Photosystem light band radiant flux 172 may define a photosystem light fraction of total radiant flux 180. Examples of photosystem light fraction include at least 10%, at least 11%, at least 12%, at least 13%, at least 14%, at least 15%, at least 16%, at least 17%, at least 18%, at most 25%, at most 24%, at most 23%, at most 22%, at most 21%, at most 20%, at most 19%, at most 18%, and/or at most 17%.

In addition to the above, and in some embodiments, LED-based horticultural light spectrum 150 may include less than a threshold far-infrared fraction of far-infrared light with a wavelength of greater than 750 nm. Examples of the threshold far-infrared fraction include fractions of at most 5%, at most 4%, at most 3%, at most 2%, and/or at most 1% of total radiant flux 180.

The above-described proportions of blue light 152, green light 154, red light 156, and near IR light 158 may permit horticultural lighting devices 10, according to the present disclosure, to provide improved, desirable photosynthetic action (e.g., growth) of plants 24 (as illustrated in FIG. 2), when horticultural lighting devices 10 provide LED-based horticultural light spectrum 150 to the plants. For example, blue light 152 may be characterized as the color that has, or provides, the lowest photosynthetic activity of a horticultural light spectrum. Also, blue light 152 may cause more light burn or damage than other horticultural light colors other than ultraviolet light. That said, at least some blue light 152 may be needed to reduce undesirable “stretching” plant growth.

Green light 154 may operate to penetrate the plant canopy and to thereby light-up more leaf area and provide greater growth. Red light 156, which includes a portion of photosystem light band 170, may provide the greatest photosynthetic activity and so may provide the greatest plant growth, including growth related to flowering.

With the above in mind, horticultural lighting device 10 configured to provide LED-based horticultural light spectrum 150 may, in some examples, provide a reduced or minimized proportion of blue light 152, a significant proportion of green light 154, and a maximized proportion of red light 156. Stated another way, radiant flux 162 may be less than radiant flux 164, which may be less than radiant flux 166. As illustrated, radiant flux 168 may be non-zero and may be less than radiant flux 162, radiant flux 164, and/or radiant flux 168.

Sufficient blue light 152 may be included to reduce undesirable “stretching” plant growth. A significant proportion of green light 154 may be included to provide penetration of the plant canopy, and a maximal proportion of red light 156 may be included to provide maximal growth power.

LED-based horticultural light spectrum 150 may provide photosystem light 170, including both photosystem I active light and photosystem II active light, simultaneously. Simultaneously providing both photosystem I active light and photosystem II active light may provide improved growth power relative to conventional LED-based horticultural lighting devices that may not be configured to simultaneously provide both photosystem I active light and photosystem II active light.

FIG. 4 illustrates a more specific example of an LED-based horticultural light spectrum 150 of relative intensity over a range of wavelengths of 400 nm (nanometers) to 800 nm, for example, according to embodiments of horticultural lighting device 10 described herein. LED-based horticultural light spectrum 150 includes blue light band 152 (e.g., 400 nm to less than 500 nm), green light band 154 (e.g., 500 nm to less than 600 nm), and red light band 156 (e.g., 600 nm to less than 700 nm). LED-based horticultural light spectrum 150 also includes near-infrared light band 158 (e.g., 700 nm -780 nm). LED-based horticultural light spectrum 150 that is illustrated in FIG. 4 is a radiometric representation of intensity, rather than a photometric representation that is weighted by human eye sensitivity. All spectra reproduced herein were collected, analyzed, and/or quantified utilizing an Everfine HAAS spectrometer.

LED-based horticultural light spectrum 150 has an overall, or total, radiant flux 180, which corresponds to the graphical area (e.g., mathematical integral) encompassed by LED-based horticultural light spectrum 150 in FIG. 4. Blue light band 152, green light band 154, red light band 156, and near IR light band 158 have corresponding radiant fluxes 162, 164, 166, and 168, respectively. Radiant fluxes 162, 164, 166, and 168 correspond to the graphical areas (e.g., mathematical integrals) encompassed by blue light band 152, green light band 154, red light band 156, and near-infrared light band 158, respectively.

Stated another way, radiant flux 162 may correspond to the area under the curve, or the mathematical integral of LED-based horticultural light spectrum 150, between 400 and 500 nanometers; and radiant flux 164 may correspond to the area under the curve, or the mathematical integral of LED-based horticultural light spectrum 150, between 500 and 600 nanometers. Similarly, radiant flux 166 may correspond to the area under the curve, or the mathematical integral of LED-based horticultural light spectrum 150, between 600 and 700 nanometers; and radiant flux 168 may correspond to the area under the curve, or the mathematical integral of LED-based horticultural light spectrum 150, between 700 and 780 nanometers. In the example of FIG. 4, radiant flux 162 of blue light 152 may be about 11% (e.g., 10.72%) of total radiant flux 180, radiant flux 164 of green light 154 may be about 28% (e.g., 27.57%) of total radiant flux 180, radiant flux 166 of red light 156 may be about 53% (e.g., 52.69%) of total radiant flux 180, and radiant flux 168 of near IR light 158 may be about 9% (e.g., 9.0%) of total radiant flux 180. In such an example, the radiant flux of light with wavelengths greater than 750 nm may be about 1% (e.g., 1.12%) of total radiant flux 180, and photosystem light band radiant flux 172 of photosystem light band 170 may be about 18% (e.g., 17.57%) of total radiant flux 180. Photosystem light band radiant flux 172 includes non-zero amounts of both photosystem I active light 167 and photosystem II active light 169.

As discussed herein with reference to FIGS. 1-2, horticultural lighting devices 10, according to the present disclosure, may include and/or utilize a plurality of LEDs 18. As also discussed, the plurality of LEDs may include both red LEDs 30 and white LEDs 32.

With regard to red LEDs 30, FIG. 5 is an illustration of a scaled light transmission spectrum 74 of relative intensity over a range of wavelengths of 400 nm to about 800 nm for an example of a wideband PC red LED 30. Scaled light transmission spectrum 74 of example wideband PC red LEDs 30 includes a full width at half maximum (FWHM) bandwidth 76 of about 80 nm and a peak transmission intensity at or about 650 nm. In contrast to wideband PC red LEDs 30, conventional red LEDs may have FWHM bandwidth of about 25 nm or less. As such, conventional red LEDs may not provide, or may not provide a desired intensity of, near IR light, photosystem I active light, and/or photosystem II active light when compared to red LEDs 30 utilized in horticultural lighting devices 10 according to the present disclosure.

In horticultural lighting devices 10 according to the present disclosure, one or more of white LEDs 32 may have one or more white light transmission spectra that, in combination with light from wideband PC red LEDs 30, may generate light with LED-based horticultural light spectrum 150.

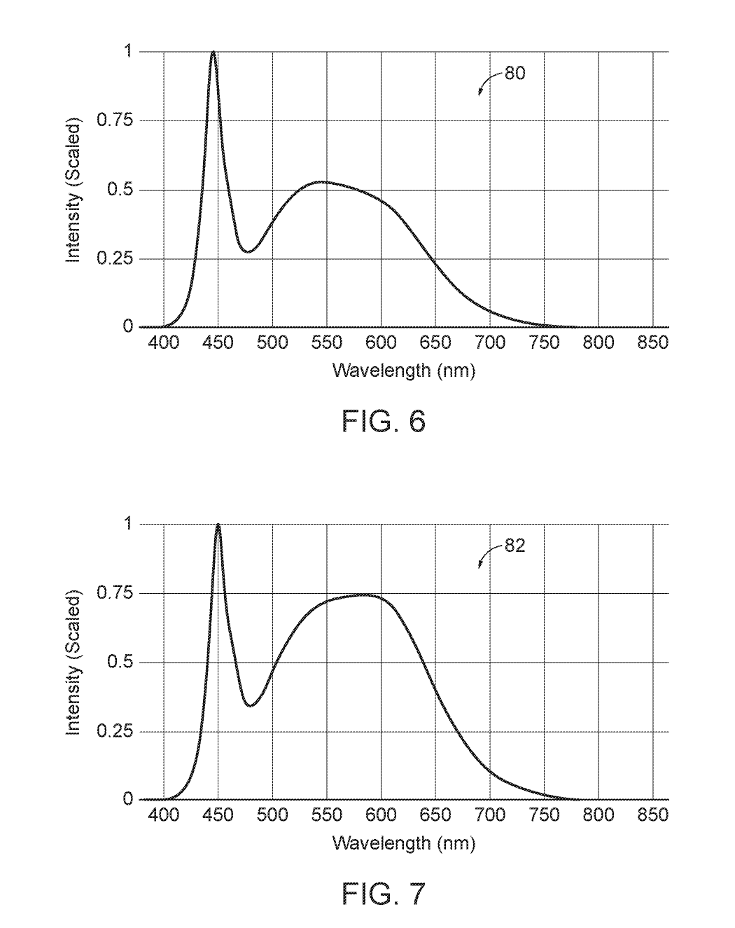

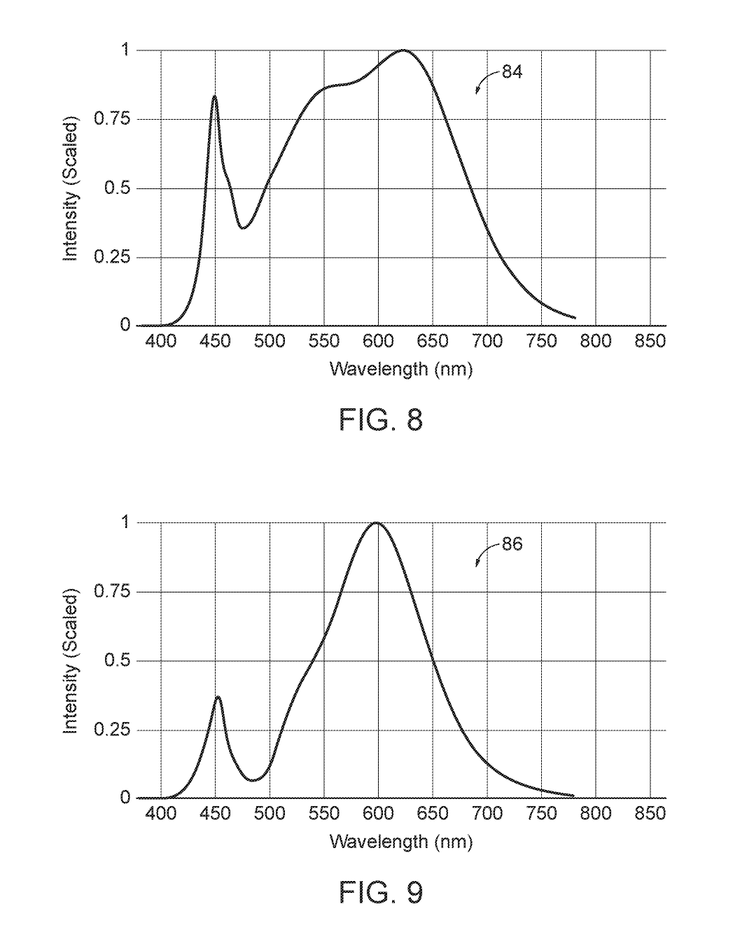

FIGS. 6-9 provide examples of scaled light transmission spectra illustrating relative intensity as a function of wavelength for various white LEDs 32 that may be utilized within horticultural lighting devices 10 and/or that may be utilized to generate LED-based horticultural light spectrum 150, according to the present disclosure. More specifically, FIG. 6 is an illustration of a scaled light transmission spectrum 80 of relative intensity over a range of wavelengths of 400 nm to about 800 nm for an example white LED 32 that may be described as having a color temperature of 6500° Kelvin and a color rending index (CRI) of 80. FIG. 7 is an illustration of a scaled light transmission spectrum 82 of relative intensity over a range of wavelengths of 400 nm to about 800 nm for an example white LED 32 that may be described as having a color temperature of 5000° Kelvin and a color rending index (CRI) of 80. FIG. 8 is an illustration of a scaled light transmission spectrum 84 of relative intensity over a range of wavelengths of 400 nm to about 800 nm for an example white LED 32 that may be described as having a color temperature of 4000° Kelvin and a color rending index (CRI) of 90. FIG. 9 is an illustration of a scaled light transmission spectrum 86 of relative intensity over a range of wavelengths of 400 nm to about 800 nm for an example white LED 32 that may be described as having a color temperature of 2700° Kelvin and a color rending index (CRI) of 80.

As discussed, horticultural lighting devices 10, according to the present disclosure, may include a plurality of LED devices 16, which may include both red LEDs 30 and white LEDs 32. In a first example, horticultural lighting device 10 may include a plurality of LED devices 16 with a first number of wideband PC red LEDs 30 and a second number of white LEDs 32, wherein the first and second numbers may be equal, or substantially equal. Moreover, the white LEDs 32 may be of two types, such as white LEDs 32 having a color temperature of 2700° Kelvin and a color rending index (CRI) of 80 and other white LEDs 32 having a color temperature of 5000° Kelvin and a color rending index (CRI) of 80.

In some examples, the two types of white LEDs 32 may be of equal, or substantially equal, numbers. In one example, horticultural lighting device 10 may include as a ratio thirty wideband PC red LEDs 30, to fifteen white LEDs 32 having a color temperature of 2700° Kelvin and a color rending index (CRI) of 80, to fifteen other white LEDs 32 having a color temperature of 5000° Kelvin and a color rending index (CRI) of 80, or corresponding proportions of such or like LEDs.

FIG. 10 is an illustration of another LED-based horticultural light spectrum 150 of relative intensity over a range of wavelengths of 400 nm to 800 nm, for example, that may be generated by examples of horticultural lighting device 10 described herein. LED-based horticultural light spectrum 150 of FIG. 10 is analogous to, or an alternative example of, LED-based horticultural light spectrum 150 of FIGS. 3-4. LED-based horticultural light spectrum 150 includes a generally blue light band, referred to as blue light 152 (e.g., 400 nm to less than 500 nm), a generally green light band, referred to as green light 154 (e.g., 500 nm to less than 600 nm), and a generally red light band, referred to as red light 156 (e.g., 600 nm to less than 700 nm). LED-based horticultural light spectrum 150 also includes a near-infrared (near IR) light band, referred to as near IR light 158 (e.g., 700 nm-780 nm). Similar to FIG. 4, LED-based horticultural light spectrum 150 of FIG. 10 is a radiometric representation of intensity, rather than a photometric representation that is weighted by human eye sensitivity.

LED-based horticultural light spectrum 150 of FIG. 10 may have an overall, or total, radiant flux 180. Blue light 152, green light 154, red light 156, and near IR light 158 have corresponding radiant fluxes 162, 164, 166, and 168, respectively. In the example of LED-based horticultural light spectrum 150 in FIG. 10, the radiant flux 162 of blue light 152 is less than the radiant flux 164 of green light 154, which is less than the radiant flux 166 of red light 156. Radiant flux 168 of near IR light 158 is non-zero and is less than each of the other radiant fluxes 162, 164, and 166. In some examples, the radiant flux 162 of blue light 152 may be 10%-17% of the total radiant flux 180, the radiant flux 164 of green light 154 may be 25%-35% of the total radiant flux 180, the radiant flux 166 of red light 156 may be 45%-55% of the total radiant flux 180, and the radiant flux 168 of near IR light 158 may be 5%-10% of the total radiant flux 180. In some examples, IR light with wavelengths greater than 750 nm may be 3% or less of the total radiant flux 180.

LED-based horticultural light spectrum 150 of FIG. 10 further may include photosystem I active light 167 (700 nm) and photosystem II active light 169 (680 nm) that are active in photosynthetic operation. Photosystem I active light 167 and photosystem II active light 169 are within photosystem light band 170 (e.g., 660 nm-720 nm) that includes photosystem I active light 167, photosystem II active light 169, and wavelengths within 20 nm of each. Photosystem light band 170 has a photosystem light band radiant flux 172 that is in the range of 15%-20% of the total radiant flux 180.

More specifically, radiant flux 162 of blue light 152 may be about 12% (e.g., 11.61%) of total radiant flux 180, radiant flux 164 of green light 154 may be about 33% (e.g., 33.11%) of total radiant flux 180, radiant flux 166 of red light 156 may be about 48% (e.g., 47.88%) of total radiant flux 180, and radiant flux 168 of near IR light 158 may be about 7% (e.g., 7.4%) of total radiant flux 180. In such an example, the radiant flux of light with wavelengths greater than 750 nm may be about 1% (e.g., 0.95%) of total radiant flux 180, and photosystem radiant flux 172 of photosystem light band 170 may be about 15% (e.g., 15.13%) of total radiant flux 180.

LED-based horticultural light spectrum 150 may be generated in any suitable manner. As an example, and as discussed herein, horticultural lighting device 10 may include multiple LED devices 16 with a first number of wideband PC red LEDs 30 and a second number of white LEDs 32. In an example horticultural lighting device utilized to generate LED-based horticultural light spectrum 150 of FIG. 10, the first number of wideband PC red LEDs 30 may be lower than the second number of white LEDs 32 (e.g., less than half, or in some examples about one-third, of the total number of LED devices). Moreover, the white LEDs 32 may be of two or more types (e.g., three types), such as white LEDs 32 having a color temperature of 2700° Kelvin and a color rending index (CRI) of 80, other white LEDs 32 having a color temperature of 4000° Kelvin and a color rending index (CRI) of 90, and still other white LEDs 32 having a color temperature of 6500° Kelvin and a color rending index (CRI) of 80.

In a specific example, such a horticultural lighting device 10 may include as a ratio seven wideband PC red LEDs 30, to eight white LEDs 32 having a color temperature of 2700° Kelvin and a color rending index (CRI) of 80, to fifteen other white LEDs 32 having a color temperature of 4000° Kelvin and a color rending index (CRI) of 90, to one other white LED 32 having a color temperature of 6500° Kelvin and a color rending index (CRI) of 80, or corresponding proportions of such or like LEDs.

As discussed herein, horticultural lighting device 10 may include a plurality of LEDs 18 that together and/or collectively may produce and/or generate LED-based horticultural light spectra 150, according to the present disclosure. Additionally or alternatively, it is within the scope of the present disclosure that a single LED, or a single type and/or class of LED, may be adapted, designed, configured, and/or constructed to produce and/or generate LED-based horticultural light spectra 150.

When horticultural lighting device 10 includes the plurality of LEDs 18, the horticultural lighting device may include any suitable number, fraction, and/or proportion of LEDs, including any suitable number, fraction, and/or proportion of wideband PC red LEDs 30 and/or of white LEDs 32 of any suitable color temperature and/or of any suitable color rending index. In addition, each LED in the plurality of LEDs may be referred to herein as generating a corresponding fraction of the total radiant flux and/or of the horticultural light spectra.

Any LED that produces a high fraction of red and/or infrared light, such as via phosphor effects, may be referred to herein as and/or may function as a red LED 30 and/or as a wideband PC red LED 30. Examples of combinations of LEDs 18 for LED-based horticultural lighting devices 10 that may produce and/or generate horticultural light spectra 150, according to the present disclosure, are summarized in Table 1, where each example (indicated by the leftmost column) includes the corresponding ratios of the correspondingly indicated LEDs.

TABLE 1

| | LED | LED Color | LED | |
|---|---|---|---|---|
| Example # | Type | Temperature | CRI | Ratio |
| 1 | Wideband PC Red | | | 2 |
| | White | 2700° Kelvin | 80 | 1 |
| | White | 5000° Kelvin | 80 | 1 |
| 2 | Wideband PC Red | | | 7 |
| | White | 2700° Kelvin | 80 | 8 |
| | White | 4000° Kelvin | 90 | 15 |
| | White | 6500° Kelvin | 80 | 1 |
| 3 | White | 2200° Kelvin | 90 | 10 |
| | White | 6500° Kelvin | 80 | 3 |

In Example #3, the 2200° Kelvin, 90 CRI, white LEDs may contain a high proportion of red phosphor and thus may function as wideband PC red LEDs as utilized in the present disclosure. Table 2 summarizes proportions of radiant flux for spectral bands generated by the example combinations of Table 1.

TABLE 2

| | | | | | % Photo- | % |
|---|---|---|---|---|---|---|
| Exam- | % Blue | % Green | % Red | % Near IR | system | Above |
| ple # | Band | Band | Band | Band | Band | 750 nm |
| 1 | 10.72% | 27.57% | 52.69% | 9.01% | 17.57% | 1.12% |
| 2 | 11.61% | 33.11% | 47.88% | 7.41% | 15.13% | 0.95% |
| 3 | 10.23% | 31.90% | 49.75% | 8.12% | 16.04% | 1.04% |

It is within the scope of the present disclosure that horticultural lighting device 10 and/or LED-based horticultural light spectra 150, which are disclosed herein, may be utilized in horticultural lighting methods, in methods of illuminating plants, and/or in methods of growing plants. Such methods may include generating LED-based horticultural light spectra 150 and/or directing LED-based horticultural light spectra toward, onto, and/or incident upon one or more growing plants. The horticultural light spectra may be generated by any suitable horticultural lighting device, including those that are disclosed herein. The horticultural light spectra may include any suitable proportion, fraction, and/or percentage of blue light, green light, red light, near-infrared light, photosystem light, and/or light above 750 nm, including those that are disclosed herein with reference to LED-based horticultural light spectra 150.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entity in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” may mean A alone, B alone, C alone, A and B together, A and C together, B and C together, A, B, and C together, and optionally any of the above in combination with at least one other entity.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase, “for example,” the phrase, “as an example,” and/or simply the term “example,” when used with reference to one or more components, features, details, structures, embodiments, and/or methods according to the present disclosure, are intended to convey that the described component, feature, detail, structure, embodiment, and/or method is an illustrative, non-exclusive example of components, features, details, structures, embodiments, and/or methods according to the present disclosure. Thus, the described component, feature, detail, structure, embodiment, and/or method is not intended to be limiting, required, or exclusive/exhaustive; and other components, features, details, structures, embodiments, and/or methods, including structurally and/or functionally similar and/or equivalent components, features, details, structures, embodiments, and/or methods, are also within the scope of the present disclosure.

Illustrative, non-exclusive examples of subject matter according to the present disclosure are described in the following enumerated paragraphs:

A. A horticultural lighting device, comprising:

a lighting fixture configured to receive and operate plural light-emitting diodes (LEDs); and

a plurality of LEDs coupled to the lighting fixture to generate light with a radiant flux, wherein:

7%-15% of the radiant flux is from light with wavelengths in a blue light band of 400 nm to less than 500 nm,

20%-40% of the radiant flux is from light with wavelengths in a green light band of 500 nm to less than 600 nm, and

45%-60% of the radiant flux is from light with wavelengths in a red light band of 600 nm to less than 700 nm.

A1. The horticultural lighting device of paragraph A, wherein 7%-13% of the radiant flux is from light with wavelengths in a near-infrared light band of 700 nm-800 nm.

A2. The horticultural lighting device of paragraph A or A1, wherein the radiant flux includes a photosystem light band with wavelengths between about 660 nm and about 720 nm, and further wherein 15-20% of the radiant flux is from light within the photosystem light band.

A3. The horticultural lighting device of paragraph A2, wherein the photosystem light band includes both photosystem II light at 680 nm and photosystem I light at 700 nm.

A4. The horticultural lighting device of any of paragraphs A-A3, wherein less than 3% of the radiant flux is from light with wavelengths greater than 750 nm.

A5. The horticultural lighting device of any of paragraphs A-A4, wherein the plurality of LEDs include a first plurality of red LEDs and a second plurality of white LEDs.

A6. The horticultural lighting device of paragraph A5, wherein the first plurality of red LEDs includes wideband PC red LEDs.

A7. The horticultural lighting device of paragraph A5 or A6, wherein the second plurality of white LEDs includes white LEDs with a color temperature of 2700° Kelvin.

A7.1. The horticultural lighting device of paragraph A7, wherein the white LEDs with the color temperature of 2700° Kelvin have a color rending index of 80.

A8. The horticultural lighting device of any of paragraphs A5-A7, wherein the second plurality of white LEDs includes white LEDs with a color temperature of 5000° Kelvin. A8.1. The horticultural lighting device of paragraph A8, wherein the white LEDs with the color temperature of 5000° Kelvin have a color rending index of 80.

A9. The horticultural lighting device of any of paragraphs A5-A8.1, wherein the second plurality of white LEDs includes white LEDs with a color temperature of 4000° Kelvin.

A9.1. The horticultural lighting device of paragraph A9, wherein the white LEDs with the color temperature of 4000° Kelvin have a color rending index of 90.

A10. The horticultural lighting device of any of paragraphs A5-A9.1, wherein the second plurality of white LEDs includes white LEDs with a color temperature of 6500° Kelvin.

A10.1. The horticultural lighting device of paragraph A10, wherein the white LEDs with the color temperature of 6500° Kelvin have a color rending index of 80.

A11. The horticultural lighting device of any of paragraphs A5-A10.1, wherein the second plurality of white LEDs includes white LEDs with a color temperature of 2200° Kelvin.

A11.1 The horticultural lighting device of paragraph A10, wherein the white LEDs with the color temperature of 2200° Kelvin have a color rending index of 90.

A12. The horticultural lighting device of any of paragraphs A-A11.1, wherein the lighting fixture includes a plurality of sockets to receive respective ones of the plurality of LEDs.

A13. The horticultural lighting device of any of paragraphs A-A12, wherein the lighting fixture further includes a power supply and LED drivers to power and operate the plurality of LEDs.

A14. The horticultural lighting device of any of paragraphs A1-A13, wherein a radiant flux generated by at least one LED in the plurality of LEDs is at least substantially different from a radiant flux generated by at least one other LED in the plurality of LEDs.

A15. The horticultural lighting device of any of paragraphs A1-A13, wherein a radiant flux generated by each LED in the plurality of LEDs is at least substantially similar to a radiant flux generated by each other LED in the plurality of LEDs.

B. A horticultural lighting method, comprising:

generating an LED-based horticultural light spectrum at a radiant flux, wherein:

(i) 7%-15% of the radiant flux is from light with wavelengths in a blue light band of 400 nm to less than 500 nm,

(ii) 20%-40% of the radiant flux is from light with wavelengths in a green light band of 500 nm to less than 600 nm, and

(iii) 45%-60% of the radiant flux is from light with wavelengths in a red light band of 600 nm to less than 700 nm; and

optionally directing the radiant flux incident upon at least one growing plant.

B1. The method of paragraph B, wherein the generating the LED-based horticultural light spectrum includes:

(i) generating a first fraction of the LED-based horticultural light spectrum with at least one wideband PC red LED; and

(ii) generating a second fraction of the LED-based horticultural light spectrum with at least one white LED.

B2. The method of paragraph B, wherein the generating the LED-based horticultural light spectrum includes generating an entirety of the LED-based horticultural light spectrum with a single LED.

B3. The method of any of paragraphs B-B2, wherein the method includes generating the LED-based horticultural light spectrum with a horticultural lighting device that includes a plurality of LEDs, and further wherein the generating the LED-based horticultural light spectrum includes contributing a respective fraction of the radiant flux with each LED in the plurality of LEDs.

B4. The method of any of paragraphs B1-B3, performed with the horticultural lighting device of any of paragraphs A1-A15.

### INDUSTRIAL APPLICABILITY

The devices and methods disclosed herein are applicable to the horticultural lighting industry.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A horticultural lighting method, comprising:
generating a light-emitting diode (LED)-based horticultural light spectrum at a radiant flux, wherein:
(i) 7%-15% of the radiant flux is from light with wavelengths in a blue light band of 400 nanometers (nm) to less than 500 nm,
(ii) 20%-40% of the radiant flux is from light with wavelengths in a green light band of 500 nm to less than 600 nm; and
(iii) 45%-60% of the radiant flux is from light with wavelengths in a red light band of 600 nm to less than 700 nm.

2. The method of claim 1, further comprising directing the radiant flux incident upon at least one growing plant.

3. The method of claim 1, wherein the generating the LED-based horticultural light spectrum includes:
(i) generating a first fraction of the LED-based horticultural light spectrum with at least one wideband PC red LED; and
(ii) generating a second fraction of the LED-based horticultural light spectrum with at least one white LED.

4. The method of claim 1, wherein the generating the LED-based horticultural light spectrum includes generating an entirety of the LED-based horticultural light spectrum with a single LED.

5. The method of claim 1, wherein the method includes generating the LED-based horticultural light spectrum with a horticultural lighting device that includes a plurality of LEDs, and further wherein the generating the LED-based horticultural light spectrum includes contributing a respective fraction of the radiant flux with each LED in the plurality of LEDs.

6. The method of claim 1, wherein the generating the LED-based horticultural light spectrum includes generating such that 7%-13% of the radiant flux is from light with wavelengths in a near-infrared light band of 700 nm-800 nm.

7. The method of claim 1, wherein the generating the LED-based horticultural light spectrum includes generating such that 15-20% of the radiant flux is from light with wavelengths in a photosystem light band of 660 nm to 720 nm.

8. The method of claim 7, wherein the photosystem light band includes both photosystem II light at 680 nm and photosystem I light at 700 nm.

9. The method of claim 1, wherein the generating the LED-based horticultural light spectrum includes generating such that at most 3% of the radiant flux is from light with wavelengths greater than 750 nm.

10. The method of claim 1, wherein the generating the LED-based horticultural light spectrum includes generating such that:
(i) at least 10% and at most 12% of the radiant flux is in the blue light band;
(ii) at least 25% and at most 35% of the radiant flux is in the green light band; and
(iii) at least 47% and at most 53% of the radiant flux is in the red light band.

11. A horticultural lighting device, comprising:
a lighting fixture configured to receive and operate plural light-emitting diodes (LEDs); and
a plurality of LEDs coupled to the lighting fixture to generate light with a radiant flux, wherein:
7%-15% of the radiant flux is from light with wavelengths in a blue light band of 400 nanometers (nm) to less than 500 nm,
20 %-40% of the radiant flux is from light with wavelengths in a green light band of 500 nm to less than 600 nm, and
45%-60% of the radiant flux is from light with wavelengths in a red light band of 600 nm to less than 700 nm.

12. The horticultural lighting device of claim 11, wherein 7%-13% of the radiant flux is from light with wavelengths in a near-infrared light band of 700 nm-800 nm.

13. The horticultural lighting device of claim 11, wherein the radiant flux includes a photosystem light band with wavelengths between about 660 nm and about 720 nm, and further wherein 15-20% of the radiant flux is from light within the photosystem light band.

14. The horticultural lighting device of claim 13, wherein the photosystem light band includes both photosystem II light at 680 nm and photosystem I light at 700 nm.

15. The horticultural lighting device of claim 11, wherein less than 3% of the radiant flux is from light with wavelengths greater than 750 nm.

16. The horticultural lighting device of claim 11, wherein a radiant flux generated by at least one LED in the plurality of LEDs is at least substantially different from a radiant flux generated by at least one other LED in the plurality of LEDs.

17. The horticultural lighting device of claim 11, wherein a radiant flux generated by each LED in the plurality of LEDs is at least substantially similar to a radiant flux generated by each other LED in the plurality of LEDs.

18. The horticultural lighting device of claim 11, wherein the plurality of LEDs includes a first plurality of red LEDs and a second plurality of white LEDs.

19. The horticultural lighting device of claim 18, wherein the first plurality of red LEDs includes wideband phosphor-converted (PC) red LEDs.

20. The horticultural lighting device of claim 18, wherein the second plurality of white LEDs includes at least one of:
(i) white LEDs with a color temperature of 2700° Kelvin and a color rending index of 80;
(ii) white LEDs with a color temperature of 5000° Kelvin and a color rending index of 80;
(iii) white LEDs with a color temperature of 4000° Kelvin and a color rending index of 90;
(iv) white LEDs with a color temperature of 6500° Kelvin and a color rending index of 80; and
(v) white LEDs with a color temperature of 2200° Kelvin and a color rending index of 90.
